(19) United States
(12) Patent Application Publication
(10) Pub. No.: US 2008/0198564 A1
(43) Pub. Date: Aug. 21, 2008

(54) Fixing mechanism for expansion card bracket

(75) Inventor: Lin-Wei Chang, Taipei (TW)

Correspondence Address: EDWARDS ANGELL PALMER & DODGE LLP, P.O. BOX 55874, BOSTON, MA, 02205, US

(73) Assignee: Inventec Corporation, Taipei (TW)

(21) Appl. No.: 11/708,276

(22) Filed: Feb. 19, 2007

(51) Int. Cl. H05K 5/00

(52) U.S. Cl. 361/759

(57) ABSTRACT

A fixing mechanism for securing in position the rear of an expansion card bracket to a circuit board of an electronic device include: a carrier secured in position to the circuit board and having a first pivotally fastening portion; a pivotally fastening element having a bottom provided with a second pivotally fastening portion vertically insertedly connectable and horizontally pivotally fastenable to the first pivotally fastening portion; a pivotal connection unit disposed between the pivotally fastening element and the rear of the expansion card bracket and adapted to connect horizontally the pivotally fastening element and the expansion card bracket; and a locking unit disposed between the pivotally fastening element and the rear of the expansion card bracket, adapted to rotate horizontally the pivotally fastening element and lock the pivotally fastening element to the expansion card bracket, thereby fastening pivotally the second pivotally fastening portion to the first pivotally fastening portion.

### BACKGROUND OF THE INVENTION

1. Field of the Invention

The present invention relates to a fixing mechanism for an expansion card bracket, and more particularly, to a fixing mechanism designed for an expansion card bracket and adapted to secure in position the rear of the expansion card bracket.

2. Description of the Prior Art

An expansion card for use in a flat-lying server is inserted into an expansion card bracket, before the expansion card bracket and a motherboard of the server are positioned side by side. The front of the expansion card bracket is positioned close to the rear wall of the casing of the server and thereby is secured in position to the casing of the server. The rear of the expansion card bracket extends toward the front of the server and is generally secured in position to a fan bracket disposed near the motherboard.

Nevertheless, expansion card brackets extending to a fan bracket are designed mostly for insertion of long expansion cards, while expansion cards of average length are inserted into short expansion card brackets. A carrier is disposed between the bottom of the rear of an existing expansion card bracket and the motherboard of a server, for lack of a fixing mechanism designed for the rear of an expansion card bracket. The bottom and the top of the carrier are respectively provided with a structurally simple tenon or slot for securing in position the motherboard and supporting the expansion card bracket.

The carrier is designed to carry an expansion card bracket in such a way as to prevent the rear of the expansion card bracket from drooping and touching the motherboard of the server, but the carrier cannot secure in position the rear of the expansion card bracket. A shake of the server may cause the expansion card bracket to separate from the carrier.

With a carrier being disposed between an expansion card bracket and a motherboard, installation of the expansion card bracket, which entails aligning the whole expansion card bracket with the tenon or slot of the carrier, is laborious and inconvenient.

Accordingly, an issue calling for urgent contemplation is about elimination of the aforesaid drawbacks of the prior art.

### SUMMARY OF THE INVENTION

In light of the aforesaid drawbacks of the prior art, it is a primary objective of the present invention to disclose a fixing mechanism for an expansion card bracket so as to allow the rear of the expansion card bracket to be secured in position.

Another objective of the present invention is to disclose a fixing mechanism for an expansion card bracket so as to facilitate installation of the expansion card bracket.

In order to achieve the above and other objectives, the present invention discloses a fixing mechanism for an expansion card bracket so as to secure in position the rear of the expansion card bracket to a circuit board of an electronic device. The fixing mechanism comprises: a carrier having a bottom and a top, the bottom being secured in position to the circuit board, the top being provided with a first pivotally fastening portion; a pivotally fastening element having a bottom provided with a second pivotally fastening portion vertically insertedly connectable and horizontally pivotally fastenable to the first pivotally fastening portion; a pivotal connection unit disposed between the pivotally fastening element and the rear of the expansion card bracket and adapted to connect pivotally and horizontally the pivotally fastening element and the expansion card bracket; and a locking unit disposed between the pivotally fastening element and the rear of the expansion card bracket, adapted to rotate pivotally and horizontally the pivotally fastening element and lock the pivotally fastening element to the expansion card bracket, and adapted to maintain an angle at which the second pivotally fastening portion is pivotally fastened to the first pivotally fastening portion, such that the rear of the expansion card bracket is secured in position to the circuit board of the electronic device.

Unlike the prior art related to a carrier only capable of carrying the rear of the expansion card bracket but not securing in position the expansion card bracket, the present invention discloses a fixing mechanism for an expansion card bracket wherein a pivotally fastening element working in conjunction with a carrier secures in position the rear of the expansion card bracket to the circuit board, thereby allowing the expansion card bracket to be firmly secured in position in the electronic device.

Unlike the prior art that is inconvenient for involving the coupling of the whole of an expansion card bracket to a carrier, the present invention discloses a fixing mechanism for an expansion card bracket wherein a carrier can be installed on the circuit board and near the rear of the expansion card bracket without overlapping the expansion card bracket with a view to speeding up the installation of the expansion card bracket.

Accordingly, a fixing mechanism disclosed in the present invention overcomes the aforesaid drawbacks of the prior art, and thus the present invention has high industrial applicability.

### BRIEF DESCRIPTION OF THE DRAWINGS

FIG. 1 is an exploded view showing a preferred embodiment of a fixing mechanism for an expansion card bracket of the present invention; and

FIGS. 2 and 3 are schematic views showing actuation of a fixing mechanism for an expansion card bracket of the present invention.

### DETAILED DESCRIPTION OF THE PREFERRED EMBODIMENT

The following specific embodiment is provided to illustrate the present invention. Persons skilled in the art can readily gain an insight into other advantages and features of the present invention based on the contents disclosed in this specification.

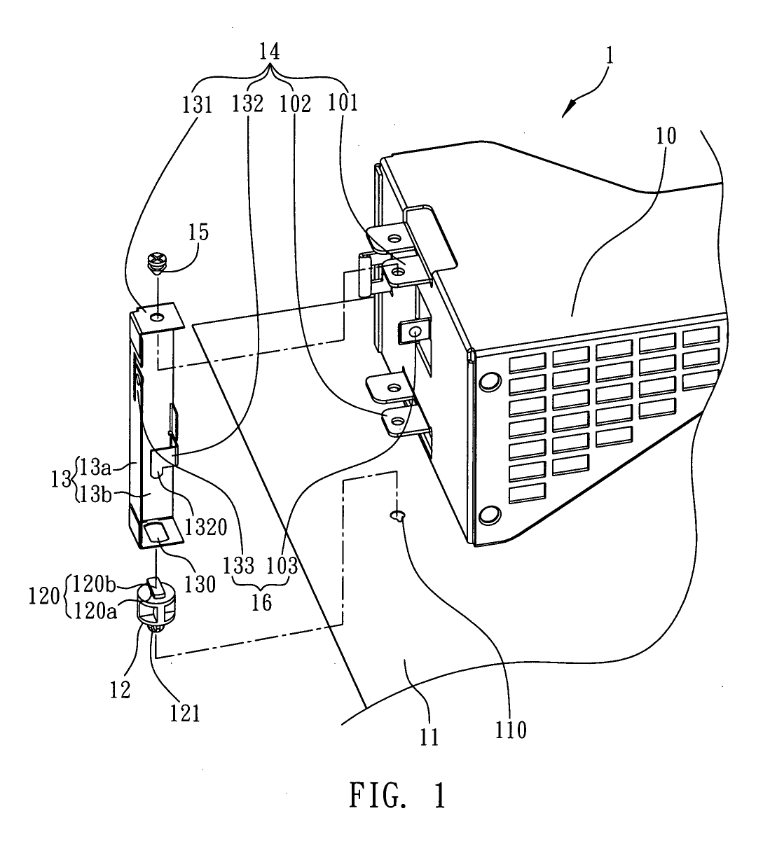

Referring to FIG. 1, an expansion card bracket 10 is installed in an electronic device 1 like a server, and the front (not shown) of the expansion card bracket 10 can be secured in position to the rear wall (not shown) of the electronic device 1. The expansion card bracket 10 is electrically inserted into a circuit board 11 of the electronic device 1.

The present invention discloses a fixing mechanism for securing in position the rear of the expansion card bracket 10 to the circuit board 11. The fixing mechanism comprises: a carrier 12 having a bottom and a top, the bottom being secured in position to the circuit board 11, the top being provided with a first pivotally fastening portion 120; a pivotally fastening element 13 having a bottom provided with a second pivotally fastening portion 130 vertically insertedly connectable and horizontally pivotally fastenable to the first pivotally fastening portion 120; a pivotal connection unit 14 disposed between the pivotally fastening element 13 and the rear of the expansion card bracket 10 and adapted to connect pivotally and horizontally the pivotally fastening element 13 and the expansion card bracket 10; and a locking unit 16 disposed between the pivotally fastening element 13 and the rear of the expansion card bracket 10, adapted to rotate pivotally and horizontally the pivotally fastening element 13 and lock the pivotally fastening element to the expansion card bracket 10, and adapted to maintain an angle at which the second pivotally fastening portion 130 is pivotally fastened to the first pivotally fastening portion 120, such that the rear of the expansion card bracket 10 is secured in position to the circuit board 11.

The bottom of the carrier 12 is provided with a resilient tenon 121 and the circuit board 11 with an opening 110. The resilient tenon 121 is locked in the opening 110 by resilient deformation so as to secure in position the carrier 12 to the circuit board 11. However, the way of securing in position the carrier 12 to the circuit board 11 is not limited to the above disclosure; for instance, the bottom of the carrier 12 may be provided with a coupling hole, and the coupling hole, coupled with a coupling element penetrating the circuit board 11 from the back and coupled to the coupling hole, secures in position the carrier 12 to the circuit board 11.

The first pivotally fastening portion 120 comprises an axle 120a and a block plate 120b horizontally formed on the top of the axle 120a, and the second pivotally fastening portion 130 is a horizontal plate with a locking hole corresponding in shape to the block plate 120b. The locking hole and the block plate 120b are bar-shaped such that a slight rotation of the second pivotally fastening portion 130 allows the second pivotally fastening portion 130 to be pivotally fastened to the first pivotally fastening portion 120.

The pivotally fastening structure of the first pivotally fastening portion 120 may be swapped for that of the second pivotally fastening portion 130. The first pivotally fastening portion 120 is a locking hole in the top of the carrier 12, and the second pivotally fastening portion comprises an axle and a block plate horizontally formed at the end of the axle and corresponding in shape to the locking hole.

The pivotal connection unit 14 comprises first and second pivotal connection plates 131 and 101, the first pivotal connection plate 131 being formed on the top of the pivotally fastening element 13 and formed with a pivotal connection hole, the second pivotal connection plate 101 being formed in the upper rear of the expansion card bracket 10 and formed with another pivotal connection hole, such that an axle element 15 penetrating the two pivotal connection holes pivotally connects the pivotally fastening element 13 and the rear of the expansion card bracket 10.

The pivotal connection unit 14 further comprises third and fourth pivotal connection plates 132 and 102, the third pivotal connection plate 132 being formed at the middle of the pivotally fastening element 13 and protrudingly formed with an axial portion 1320 extending downward, the fourth pivotal connection plate 102 being formed in the lower rear of the expansion card bracket 10 and formed with another pivotal connection hole.

The way of pivotally connecting the pivotally fastening element 13 to the expansion card bracket 10 is variable and thereby is not limited to the above disclosure. All existing pivotal connection structures are known art and thereby are not described herein one by one.

The pivotally fastening element 13 comprises a plate body. The locking unit 16 comprises a leaf spring 133 and a plate 103. The leaf spring 133 is formed at the end of the plate body and formed with a tenon. The plate 103 is protrudingly formed in the rear of the expansion card bracket 10 and formed with a slot. Engaging the tenon with the slot locks the pivotally fastening element 13 in the rear of the expansion card bracket 10.

The structure of the locking unit is variable, not limited to the above disclosure, and known to persons skilled in the art, and thereby not described in detail herein.

To reinforce the structure of the pivotally fastening element 13 and prevent the pivotally fastening element 13 from bending, the pivotally fastening element comprises two plate bodies 13a and 13b perpendicularly connected to one another.

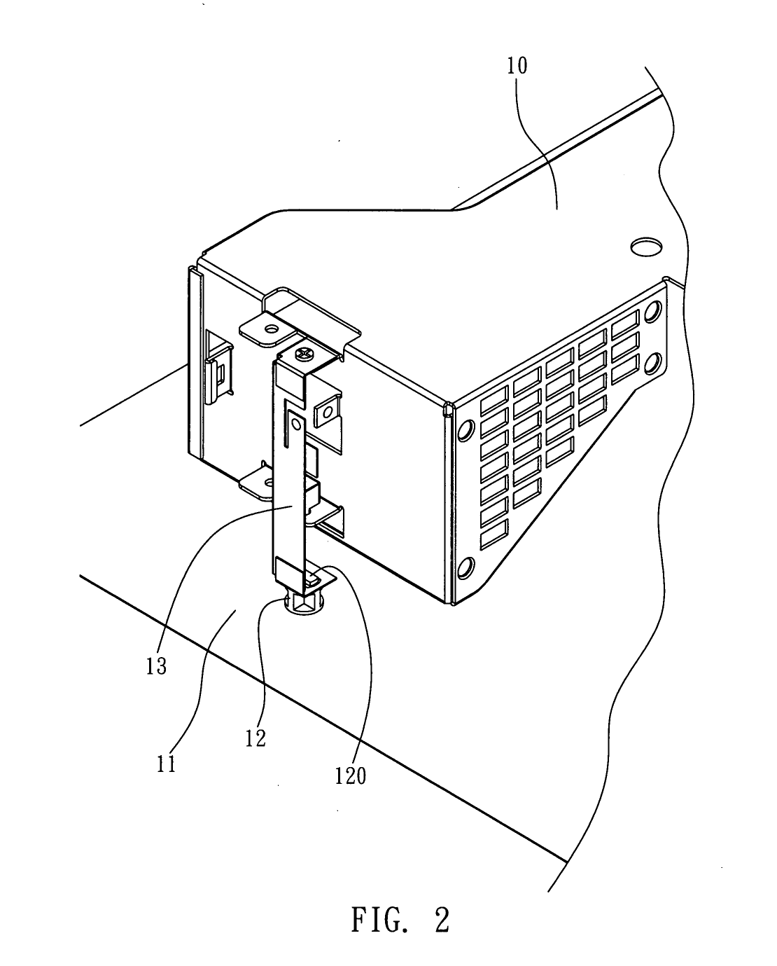

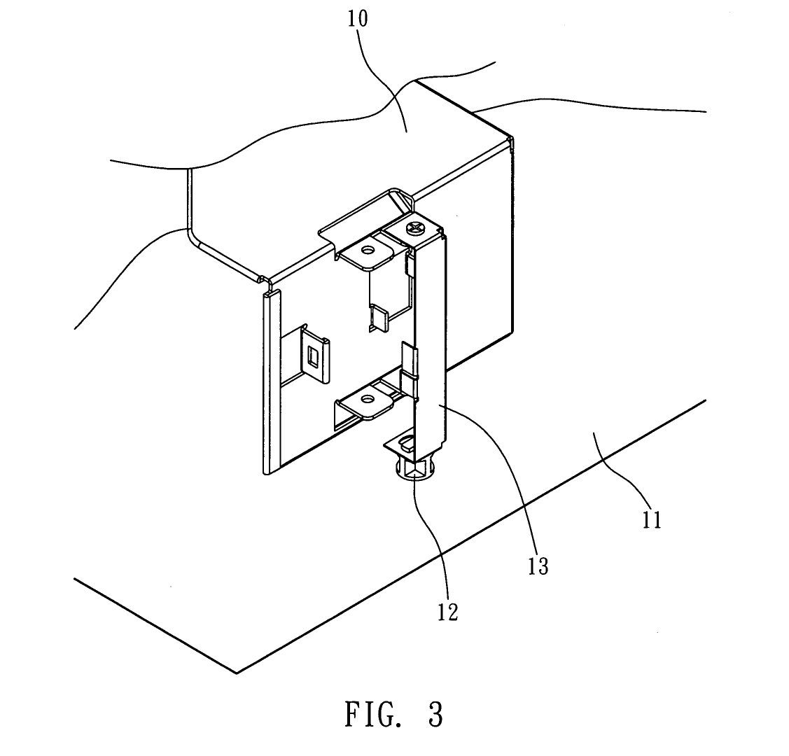

Refer to FIGS. 2 and 3. The carrier 12 is secured in position to the circuit board 11, before the expansion card bracket 10 is installed in the electronic device 1. Then, the second pivotally fastening portion 130 of the pivotally fastening element 13 pivotally connected to the rear of the expansion card bracket 10 is vertically insertedly connected to the first pivotally fastening portion 120 of the carrier 12. Lastly, the pivotally fastening element 13 is rotated and thereby locked to the rear of the expansion card bracket 10. As a result, pivotally fastening the second pivotally fastening portion 130 to the first pivotally fastening portion 120 allows the rear of the expansion card bracket 10 to be secured in position to the circuit board 11.

Unlike the prior art related to a carrier only capable of carrying the rear of the expansion card bracket but not securing in position the expansion card bracket, the present invention discloses a fixing mechanism for an expansion card bracket wherein a pivotally fastening element 13 working in conjunction with a carrier 12 secures in position the rear of the expansion card bracket 10 to the circuit board 11, thereby allowing the expansion card bracket 10 to be firmly secured in position in the electronic device 1.

Unlike the prior art that causes inconvenience by installing an expansion card bracket on a motherboard and then coupling the expansion card bracket to a carrier, the present invention discloses a fixing mechanism for an expansion card bracket wherein a carrier 12 can be installed on the circuit board 11 and near the rear of the expansion card bracket 10 without overlapping the expansion card bracket 10 with a view to speeding up the installation of the expansion card bracket 10.

Accordingly, a fixing mechanism disclosed in the present invention overcomes the aforesaid drawbacks of the prior art, and thus the present invention has high industrial applicability.

The aforesaid embodiment merely serves as the preferred embodiment of the present invention. The aforesaid embodiment should not be construed as to limit the scope of the present invention in any way. Hence, any other changes can actually be made in the present invention. It will be apparent to those skilled in the art that all equivalent modifications or changes made to the present invention, without departing from the spirit and the technical concepts disclosed by the present invention, should fall within the scope of the appended claims.

What is claimed is:

1. A fixing mechanism for securing in position the rear of an expansion card bracket to a circuit board of an electronic device, the fixing mechanism comprising:
a carrier having a bottom and a top, the bottom being secured in position to the circuit board, the top being provided with a first pivotally fastening portion;
a pivotally fastening element having a bottom provided with a second pivotally fastening portion vertically insertedly connectable and horizontally pivotally fastenable to the first pivotally fastening portion;
a pivotal connection unit disposed between the pivotally fastening element and the rear of the expansion card bracket and adapted to connect pivotally and horizontally the pivotally fastening element and the expansion card bracket; and
a locking unit disposed between the pivotally fastening element and the rear of the expansion card bracket, adapted to rotate pivotally and horizontally the pivotally fastening element and lock the pivotally fastening element to the expansion card bracket, and adapted to maintain an angle at which the second pivotally fastening portion is pivotally fastened to the first pivotally fastening portion, such that the rear of the expansion card bracket is secured in position to the circuit board of the electronic device.

2. The fixing mechanism for an expansion card bracket of claim 1, wherein the bottom of the carrier is provided with a resilient tenon and the circuit board with an opening such that the resilient tenon is locked in the opening by resilient deformation.

3. The fixing mechanism for an expansion card bracket of claim 1, wherein the first pivotally fastening portion comprises an axle and a block plate horizontally formed on the top of the axle, and the second pivotally fastening portion is a horizontal plate with a locking hole corresponding in shape to the block plate.

4. The fixing mechanism for an expansion card bracket of claim 3, wherein the locking hole and the block plate are bar-shaped.

5. The fixing mechanism for an expansion card bracket of claim 1, wherein the first pivotally fastening portion is a locking hole in the top of the carrier, and the second pivotally fastening portion comprises an axle and a block plate horizontally formed at the end of the axle and corresponding in shape to the locking hole.

6. The fixing mechanism for an expansion card bracket of claim 5, wherein the locking hole and the block plate are bar-shaped.

7. The fixing mechanism for an expansion card bracket of claim 1, wherein the pivotal connection unit comprises first and second pivotal connection plates, the first pivotal connection plate being formed on the top of the pivotally fastening element and formed with a pivotal connection hole, the second pivotal connection plate being formed in the rear of the expansion card bracket and formed with another pivotal connection hole, such that an axle element penetrating the two pivotal connection holes pivotally connects the pivotally fastening element and the rear of the expansion card bracket.

8. The fixing mechanism for an expansion card bracket of claims 7, wherein the pivotal connection unit further comprises third and fourth pivotal connection plates, the third pivotal connection plate being formed at the middle of the pivotally fastening element and protrudingly formed with an axial portion extending downward, the fourth pivotal connection plate being formed in the rear of the expansion card bracket and formed with another pivotal connection hole.

9. The fixing mechanism for an expansion card bracket of claims 1, wherein the pivotal connection unit comprises third and fourth pivotal connection plates, the third pivotal connection plate being formed at the middle of the pivotally fastening element and protrudingly formed with an axial portion extending downward, the fourth pivotal connection plate being formed in the rear of the expansion card bracket and formed with another pivotal connection hole.

10. The fixing mechanism for an expansion card bracket of claim 1, wherein the locking unit comprises a leaf spring and a plate, the leaf spring being formed on the pivotally fastening element and formed with a tenon, the plate being protrudingly formed in the rear of the expansion card bracket and formed with a slot, such that engaging the tenon with the slot locks the pivotally fastening element in the rear of the expansion card bracket.

11. The fixing mechanism for an expansion card bracket of claim 1, wherein the pivotally fastening element comprises two plate bodies perpendicularly connected to one another.
